(19) United States
(12) Patent Application Publication
(10) Pub. No.: US 2012/0120543 A1
(43) Pub. Date: May 17, 2012

(54) ION PROTECTION TECHNIQUE FOR ELECTRONIC SYSTEM WITH FLOW BETWEEN INTERNAL AIR PLENUM AND AN EHD DEVICE

(75) Inventors: Nels Jewell-Larsen, San Jose, CA (US); Kenneth Honer, Santa Clara, CA (US); Matthew Schwiebert, Cupertino, CA (US); Ron Goldman, Oakland, CA (US); Gustavo Joseph, Oakland, CA (US)

(73) Assignee: TESSERA, INC., San Jose, CA (US)

(21) Appl. No.: 13/281,169

(22) Filed: Oct. 25, 2011

Related U.S. Application Data
(60) Provisional application No. 61/412,677, filed on Nov. 11, 2010.
(60) Provisional application No. 61/530,837, filed on Sep. 2, 2011.

(51) Int. Cl. H05K 7/20; B23P 11/00; H01T 23/00; F28D 15/00

(52) U.S. Cl. 361/231; 165/104.34; 29/428

(57) ABSTRACT

Techniques are described for integration of EHD-type air movers with electronic systems, and in particular, for limiting infiltration of ions and/or charged particulates into an internal air plenum. In some designs, it may be desirable to allow or even encourage EHD motivated air flow (whether drawn or forced) through the internal air plenum while providing a barrier to transit of ions and/or charged particulates that may be generated during EHD operation. Such a barrier may employ electrostatic forces to impede transit of ions and/or charged particulate across a vent positioned to allow air flow from or into the internal air plenum. In some cases, an electrostatic barrier may include a fluid permeable mesh or grill that spans a substantial cross-section of the vent.

### BACKGROUND

Many devices or systems, whether electronic, optical, or mechanical, may include, provide or require forced flow of air or some other fluid. In some cases, the forced flow is useful to cool or otherwise moderate heat generated by thermal sources within the device or system. In such cases, cooling or thermal moderation may help prevent device overheating, reduce thermal hotspots, provide desired thermal stability for temperature sensitive devices, improve long term reliability or provide other benefits. In some cases, forced flow may be a primary function of the device or system.

It is known in the art to provide cooling air flow by using fans, blowers or other similar moving mechanical devices; however, such devices generally have limited operating lifetimes, tend to produce undesired noise or vibration, consume power or suffer from other design problems. In addition, such devices can often impose constraints of geometry, form factor and/or layout in systems for which they provide cooling air flows. These constraints can be particularly problematic in modern consumer electronics devices for which size, and indeed “thinness,” have become important market differentiators.

In some applications, the use of an ion flow air mover device, such as an electrohydrodynamic (EHD) device or electro-fluid dynamic (EFD) device, may result in improved cooling efficiency and reduced vibrations, power consumption, electronic device temperatures, and noise generation. In such deployments, an EHD air mover may reduce costs, allow for reduced device size, thickness or volume, and may in some cases improve electronic device performance and/or user experience.

EHD-type air movers and other similar devices can produce ions, charged particulate and ozone, as well as electromagnetic interference (EMI). Some electronic system components may be adversely affected by ions, charged particulate or ozone that migrate or diffuse throughout a system or enclosure. Likewise, transient arcing or sparking events may present EMI mitigation challenges. In some cases, the potential for adverse effects may be accentuated as system form factors and standoffs decrease and as EHD-type air movers or other similar devices are advantageously situated to provide air flows precisely where needed in such designs. Accordingly, improvements are sought in mitigating exposure or the effects of exposure of electronic system components to ions, charged particulate, ozone and/or EMI.

### SUMMARY

The present invention relates generally to integration of EHD-type air movers with electronic systems, and in particular, to techniques for limiting infiltration of ions and/or charged particulates into an internal air plenum. In some designs, it may be desirable to allow or even encourage EHD motivated air flow (whether drawn or forced) through the internal air plenum while providing a barrier to transit of ions and/or charged particulates that may be generated during EHD operation. Such a barrier may employ electrostatic forces to impede transit of ions and/or charged particulate across a vent positioned to allow air flow from or into the internal air plenum. In some cases, an electrostatic barrier may include a fluid permeable mesh or grill that spans a substantial cross-section of the vent. In some cases, an electrostatic barrier need only be positioned adjacent such a vent to exert electrostatic forces on ions and charged particulate that might otherwise transit the vent. In some cases, an electrostatic barrier may be coupled to power supply voltages and thereby achieve a desired potential. In some cases, a dielectric or electrically isolated conductive surface may accumulate sufficient charge (e.g., by ion impingement) to thereafter exert the desired electrostatic forces and impede further ion and charged particulate transit through the vent. In general, such electrostatically operative barriers are referred to herein as “ion barriers.”

In some embodiments in accordance with the present invention, an electronic system includes an enclosure and a plurality of electronic components within the enclosure having respective surfaces exposed to an internal air plenum. The enclosure has inlet and outlet ventilation boundaries together with an EHD air mover disposed therein to internal air plenum along a flow path between the inlet and outlet ventilation boundaries, wherein at least a portion of the flow path transits the internal air plenum. An ion barrier is positioned to impede ion migration from the EHD air mover into the internal air plenum.

In some embodiments, the electronic system further includes a boundary wall that at least partially defines the internal air plenum. A secondary vent is positioned to allow at least a portion of the motivated air flow to transit the internal air plenum. In some cases, the secondary vent includes an opening through the boundary wall. In some cases, the ion barrier is positioned proximate to the secondary vent to impede ion migration therethrough. In some cases, the ion barrier is positioned in, or proximate to, an inlet portion of the EHD air mover to impede ion migration toward the secondary vent. In some embodiments, the electronic system further includes an additional ion barrier positioned proximate to the secondary vent to further impede ion migration from the EHD air mover into the internal air plenum.

In some embodiments, the ion barrier is positioned in, or proximate to, an inlet portion of the EHD air mover to impede ion migration toward the internal air plenum. In some embodiments, the ion barrier includes one or more surfaces interposed upstream of an emitter electrode of the EHD air mover in a portion of the flow path between the internal air plenum and the emitter electrode. In some cases, the one or more surfaces of the interposed ion barrier are configured to collect and retain charge that migrates from the emitter electrode during operation of the EHD air mover such that migration or flow of further ions or charged particulate is impeded by repulsive electrostatic force. In some cases, the one or more surfaces of the interposed ion barrier are coupled to a repelling electrical potential such that migration or flow of ions or charged particulate is impeded by repulsive electrostatic force.

In some embodiments, the ion barrier includes at least one of an electrostatically chargeable wire, rod, strip, grill, mesh and screen. In some embodiments, the ion barrier includes one or more electrostatically chargeable side walls along the flow path. In some embodiments, the ion barrier includes an electrostatically chargeable surface of an electrode conditioning mechanism. For example, in some cases, the electrostatically chargeable surface of the electrode conditioning mechanism includes an elongate guide shaft, drive screw or worm gear interposed in the flow path.

In some embodiments, the ion barrier is formed, at least in part, of dielectric or electrically isolated conductive material that accumulates static charge during operation of the EHD air mover. In some embodiments, the ion barrier is formed, at least in part, of conductive material coupled to an ion repelling potential. In some embodiments, the ion barrier is formed as or of a fluid permeable material. In some embodiments, the ion barrier includes one or more surfaces interposed downstream of a collector electrode of the EHD air mover in a portion of the flow path between the collector electrode and the internal air plenum. For example, in some cases, the one or more surfaces of the interposed ion barrier are coupled to a repelling electrical potential such that migration or flow of ions or charged particulate is impeded by repulsive electrostatic force. In some cases, the one or more surfaces of the interposed ion barrier are configured to collect and retain charge that migrates or flows from an emitter electrode past the collector electrode during operation of the EHD air mover such that migration or flow of ions or charged particulate is impeded by repulsive electrostatic force.

In some embodiments, the ion barrier includes an ion repelling portion and an adjacent ion attracting portion, the ion repelling and attracting portions closely proximate but oriented such that the ion repelling portion is interposed in or along the flow between an emitter electrode and the internal air plenum.

In some embodiments, the electronic system includes ozone catalytic or reactive material disposed on surfaces exposed to the internal air plenum. In some embodiments, the electronic system includes ozone resistant or tolerant coatings on surfaces exposed to the internal air plenum.

In some embodiments, a substantial portion of the air flow motivated by the EHD air mover is drawn through the internal air plenum. In some embodiments, a substantial portion of the air flow motivated by the EHD air mover is forced through the internal air plenum.

In some embodiments in accordance with the present invention, a method of ventilating an electronic system includes: (i) with an EHD air mover, generating ions and accelerating the generated ions in the presence of an electrical field to thereby motivate air flow over heat transfer surfaces and along a flow path between inlet and outlet ventilation boundaries of an enclosure, wherein at least a portion of the air flow transits an internal air plenum housing a plurality of electronic components; and (ii) electrostatically impeding ion migration from the EHD air mover into the internal air plenum.

In some embodiments, the method includes collecting and retaining (on a surface interposed in or along the flow path) charge that migrates from an emitter electrode during operation of the EHD air mover such that migration or flow of further ions or charged particulate is impeded by repulsive electrostatic force. In some embodiments, the method includes: charging a surface interposed in or along the flow path to a repelling electrical potential such that migration or flow of ions or charged particulate is impeded by repulsive electrostatic force.

In some cases, the internal air plenum is upstream of the EHD air mover relative to the motivated air flow. In some cases, the internal air plenum is downstream of the EHD air mover relative to the motivated air flow.

In some embodiments, the method includes drawing air from the internal air plenum into the motivated air flow, wherein the electrostatically impeded ion migration includes upstream migration into the internal air plenum of ions generated at an emitter electrode of the EHD air mover. In some embodiments, the method includes exhausting a portion of the motivated air flow through the internal air plenum, wherein the electrostatically impeding includes diverting away from the internal air plenum ions or charged particulate entrained in the motivated air flow downstream of a collector electrode of the EHD air mover.

In some embodiments, the method includes transiting at least a portion of the air flow through the internal air plenum and over ozone catalytic or reactive material on exposed surfaces within the internal air plenum. In some embodiments, the method includes transiting at least a portion of the air flow through the internal air plenum and past ozone resistive or tolerant coatings on exposed surfaces within the internal air plenum.

In some embodiments in accordance with the present invention, a method of making a product includes (i) positioning an EHD air mover within an electronic device enclosure to motivate air flow along a flow path between the inlet and outlet ventilation boundaries of the electronic device enclosure; and (ii) providing within the electronic device enclosure an ion barrier positioned therewithin to substantially impede migration of ions generated at an emitter electrode of the EHD air mover into an internal air plenum.

In some embodiments, the method includes providing a secondary vent in a boundary wall positioned to at least partially define the internal air plenum. In some embodiments, the method includes providing an electrostatically chargeable wire, rod, strip, grill, mesh or screen across or proximate to the secondary vent to at least partially define the ion barrier. In some embodiments, the method includes providing an electrostatically chargeable surface in, or proximate to, an inlet portion of the EHD air mover to collect impede upstream ion migration toward the internal air plenum.

In some cases, the provided electrostatically chargeable surface includes at least one of: a wire, rod, strip, grill, mesh and screen; and side walls along the flow path formed of dielectric material. In some embodiments, the method includes providing an electrode conditioning mechanism operable at successive times throughout the operating life of the EHD air mover, wherein the electrostatically chargeable surface includes an elongate guide shaft, drive screw or worm gear of the electrode conditioning mechanism interposed in the flow path.

These and other embodiments will be understood with reference to the description herein, the drawings and the appended claims.

### BRIEF DESCRIPTION OF THE DRAWINGS

The present invention may be better understood, and its numerous objects, features, and advantages made apparent to those skilled in the art by referencing the accompanying drawings.

FIG. 1A is a depiction of certain basic principles of electrohydrodynamic (EHD) fluid flow. FIG. 1B depicts a side cross-sectional view of an illustrative EHD air mover device.

FIGS. 2A, 2B, 2C and 2D depict plan views of various illustrative EHD air mover and internal plenum configurations in which an ion barrier is positioned at, or adjacent to, a secondary vent that allows air flow between the internal air plenum and the EHD motivated flow path, but impedes ion and/or charged particulate infiltration into the internal air plenum. Although scale and form factors illustrated in the configurations of FIGS. 2A, 2B, 2C and 2D are reminiscent of pad-type consumer electronics devices, persons of ordinary skill in the art will recognize applicability to a wide variety of devices.

FIGS. 3 and 4 depict plan views of illustrative laptop-oriented configurations of an EHD air mover and components within an internal plenum. In FIG. 3, an ion barrier is positioned at, or adjacent to, a secondary vent that allows air flow between the internal air plenum and the EHD motivated flow path, but impedes ion and/or charged particulate infiltration into the internal air plenum. In FIG. 4, an ion barrier is positioned at, adjacent to, or is integral with an intake portion of the EHD air mover and impedes ion and/or charged particulate migration back into the internal air plenum.

FIG. 5 depicts a plan view of an illustrative pad-type device configuration of an EHD air mover and components within an internal plenum in which an ion barrier is positioned at, adjacent to, or is integral with an intake portion of the EHD air mover and impedes ion and/or charged particulate migration back into the internal air plenum. FIG. 6 depicts (in plan view) a variation in which, in addition to the intake-positioned ion barrier, and additional ion barrier is positioned at, or adjacent to, a secondary vent that allows air flow between the internal air plenum and the EHD motivated flow path. The additional ion barrier impedes ion and/or charged particulate infiltration into the internal air plenum.

FIGS. 7, 8, 9A, 10 and 11 depict side cross-sectional view of illustrative EHD air mover designs suitable for use in various of the device configurations illustrated herein. In particular, FIG. 7 depicts an EHD air mover design in which dielectric suitable to capture and retain charge along sidewalls upstream of an emitter electrode provides a barrier to upstream migration of ions. FIG. 8 adds optional ion sinks to enhance performance of an EHD intake positioned ion barrier. FIG. 9A provides a upstream screw drive or worm gear that provides additional upstream charge capture and retaining surfaces as part of an EHD intake positioned ion barrier. FIGS. 10 and 11 depict additional sidewall features that contribute to field shaping with the illustrated EHD channels.

FIG. 9B depicts in perspective view an upstream screw drive or worm gear usable to cause a carriage (including electrode conditioning and/or cleaning surfaces thereof) to frictionally engage emitter and collector electrode surfaces of an illustrative EHD air mover. In the illustrated configuration, the screw drive or worm gear provides additional upstream charge capture and retaining surfaces as part of an EHD intake positioned ion barrier. Dielectric sidewalls (see corresponding FIG. 9A) are omitted so as not to obstruct interior view.

The use of the same reference symbols in different drawings indicates similar or identical items.

### DESCRIPTION OF THE PREFERRED EMBODIMENT(S)

Devices built using the principle of ionic movement of a fluid are variously referred to in the literature as ionic wind machines, electric wind machines, corona wind pumps, electro-fluid-dynamics (EFD) devices, electrostatic fluid accelerators (EFAs), electrohydrodynamic (EHD) thrusters and EHD gas pumps. Some aspects of the technology have also been exploited in devices referred to as electrostatic air cleaners or electrostatic precipitators. In general, EHD technology uses ion flow principles to move fluids (e.g., air molecules). Basic principles of EHD fluid flow are reasonably well understood by persons of skill in the art. Accordingly, a brief illustration of ion flow using corona discharge principles in a simple two-electrode system sets the stage for the more detailed description that follows.

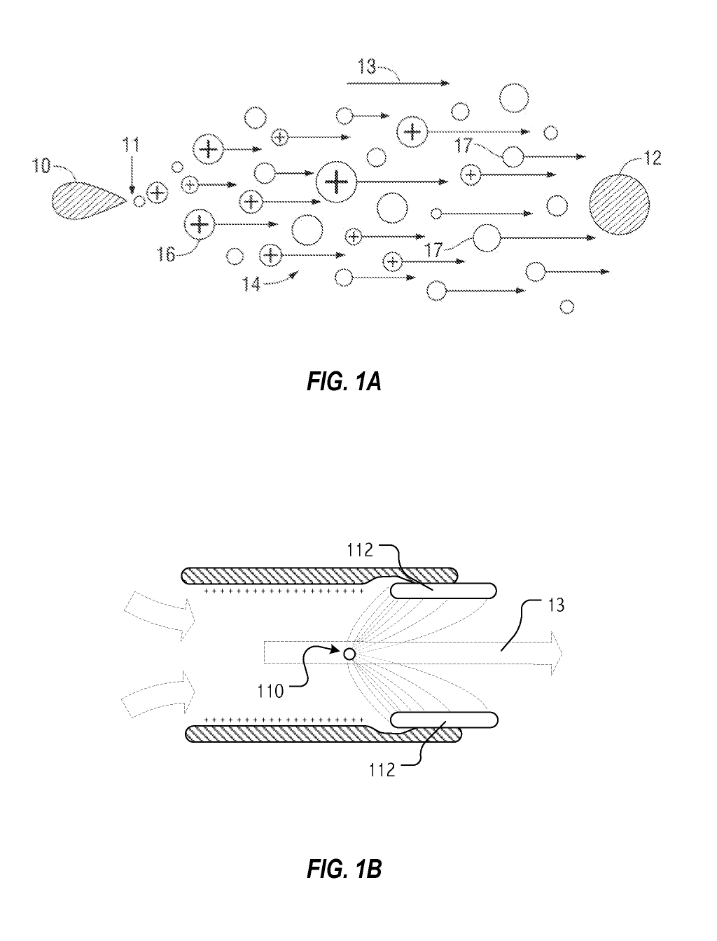

With reference to the illustration in FIG. 1A, EHD principles include applying a high intensity electric field between a first electrode 10 (often termed the “corona electrode,” the “corona discharge electrode,” the “emitter electrode” or just the “emitter”) and a second electrode 12. Fluid molecules, such as surrounding air molecules, near the emitter discharge region 11, become ionized and form a stream 14 of ions 16 that accelerate toward second electrode 12, colliding with neutral fluid molecules 17. During these collisions, momentum is imparted from the stream 14 of ions 16 to the neutral fluid molecules 17, inducing a corresponding movement of fluid molecules 17 in a desired fluid flow direction, denoted by arrow 13, toward second electrode 12. Second electrode 12 may be variously referred to as the “accelerating,” “attracting,” “target” or “collector” electrode. While stream 14 of ions 16 is attracted to, and generally neutralized by, second electrode 12, neutral fluid molecules 17 continue past second electrode 12 at a certain velocity. The movement of fluid produced by EHD principles has been variously referred to as “electric,” “corona” or “ionic” wind and has been defined as the movement of gas induced by the movement of ions from the vicinity of a high voltage discharge electrode 10.

Notwithstanding the descriptive focus on corona discharge type emitter electrode configurations, persons of ordinary skill in the art will appreciate that ions may be generated by other techniques such as silent discharge, AC discharge, dielectric barrier discharge (DBD), or the like, and once generated, may, in turn, be accelerated in the presence of electrical fields to motivate fluid flow as described herein. For avoidance of doubt, emitter electrodes need not be of a corona discharge type in all embodiments. Also for avoidance of doubt, power supply voltage magnitudes, polarities and waveforms (if any) described or illustrated with respect to particular embodiments are purely illustrative and may differ for other embodiments.

In general, practical EHD air mover implementations may include electrode geometries, channel designs and field shaping features, EMI shielding and/or duct work and heat transfer surfaces that have been adapted for a given application or deployment. FIG. 1B depicts a side cross-sectional view of an illustrative EHD air mover that has been developed for thin form factor consumer electronics device applications. Although embodiments in accordance with the present inventions need not employ EHD air mover designs akin to that illustrated in FIG. 1 or described elsewhere herein, persons of ordinary skill in the art will appreciate suitable adaptations of the techniques described herein to systems that include EHD air movers of alternative design.

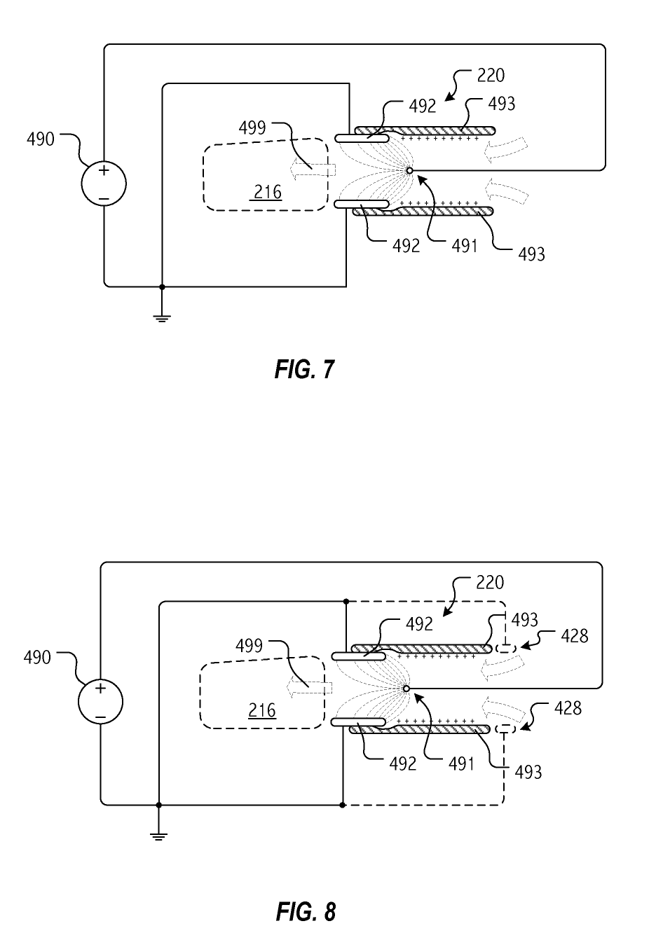

Accordingly, in view of the foregoing, and without limitation, in the EHD air mover illustrated in FIG. 1, a high intensity electric filed is established between an emitter electrode 110 and a pair of collector electrodes 112. Although power supply connections are omitted for clarity, exemplary field lines show the direction in which individual ions are accelerated to motivate a net downstream fluid flow 13. Further detail, and variations on the basic EHD air mover design illustrated, are provided with reference to FIGS. 7, 8, 9A, 9B, 10 and 11, which follow. But first, we turn in ion barrier designs.

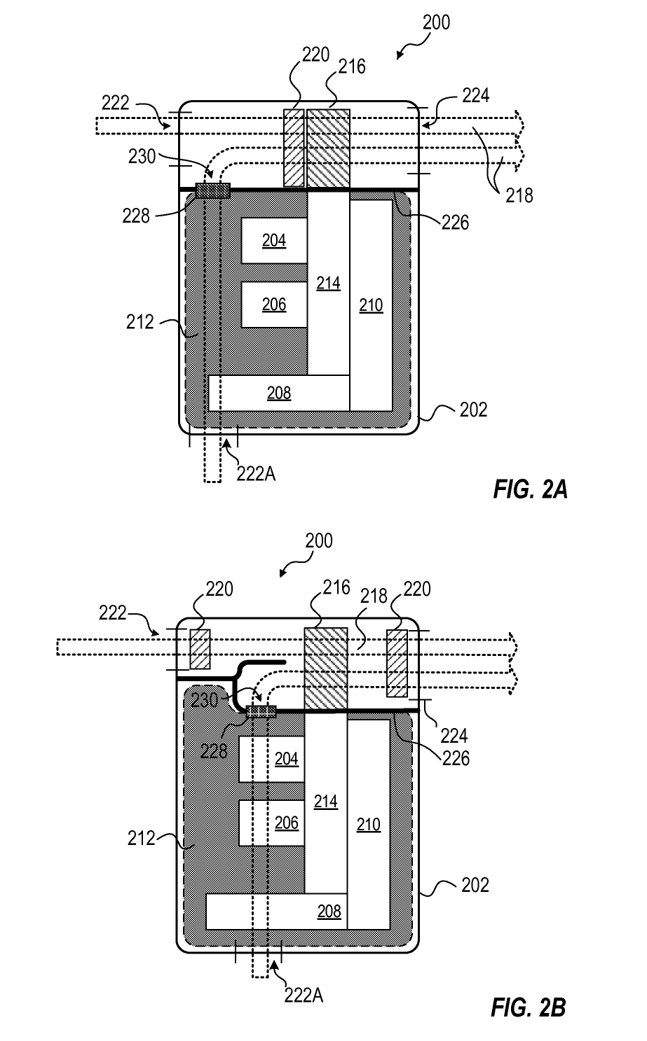

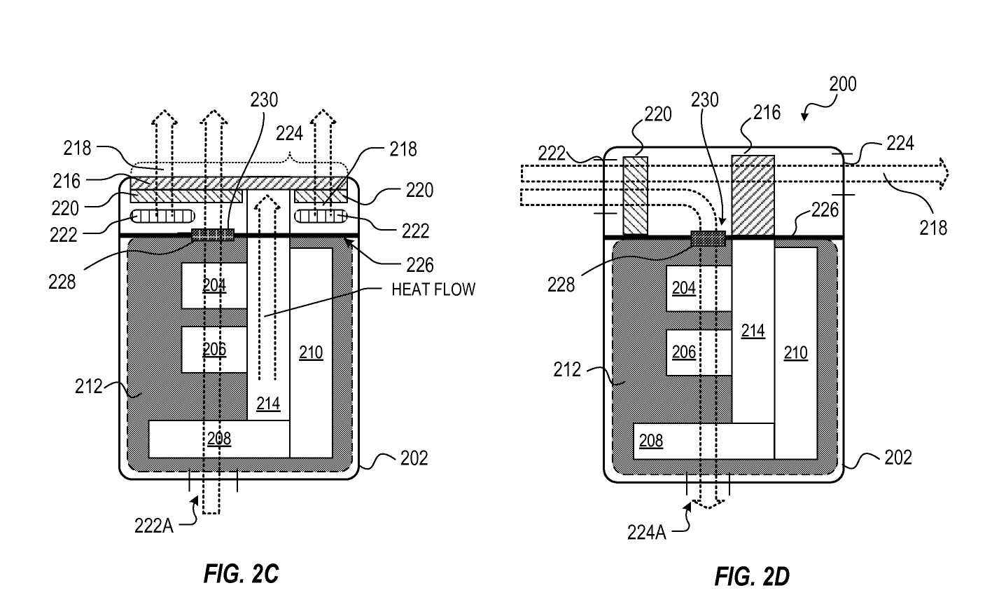

FIGS. 2A, 2B, 2C and 2D depict plan views of various illustrative EHD air mover and internal plenum configurations and of flow topologies in which an ion barrier is positioned at, or adjacent to, a secondary vent. The secondary vent allows air flow between the internal air plenum and the EHD motivated flow path, but impedes ion and/or charged particulate infiltration into the internal air plenum. Scale and form factors illustrated in the configurations of FIGS. 2A, 2B, 2C and 2D are reminiscent of pad- or smartphone-type consumer electronics devices. Nonetheless, persons of ordinary skill in the art will recognize applicability of the illustrated ion barrier and EHD air mover designs described herein to a wide variety of devices. Likewise, flow topologies are purely illustrative and placements of ventilation boundaries and internal components are subject to a wide degree of design variation to accommodate a given implementation or deployment. Based on the description herein, persons of ordinary skill in the art will appreciate varied designs and suitable positioning (in such varied designs) of ion barriers to impede ion and in some cases charged particulate into an internal air plenum.

Turning first to FIG. 2A, an electronic system 200 includes an enclosure 202 housing various exemplary electronic components, e.g., a microprocessor 204, graphics unit 206, battery 208 and a display illumination source 210, any or all of which may generate heat during operation of the electronic system. Enclosure 202 further defines an internal plenum 212 housing one or more of the electronic components. A heat pipe 214 or other heat transfer path conveys heat from one or more of the electronic components within the internal plenum 212 to a heat transfer surface(s) 216 positioned in the path of an air flow 218 motivated by an EHD air mover 220. Note that heat pipe 214 and possible heat sources are illustrated schematically. Accordingly, specific depictions are not meant to suggest limitation to any particular topology of heat transfer pathways from particular thermal sources (e.g., electronic components, illumination sources) to heat transfer surface(s) 216. Rather, based on the description herein, persons of ordinary skill in the art will recognize topological variations suitable for heat transfer needs of particular systems or devices. The enclosure 202 has inlet and outlet ventilation boundaries 222 and 224 and the EHD air mover 220 motivates air flow along a flow path between the inlet and outlet ventilation boundaries 222 and 224.

In general, it is desirable to limit migration or infiltration of ions into the internal plenum 212. Ions generated in corona discharge conditions of the EHD air mover 220 into internal plenum 212 may adversely affect sensitive electronic components by contributing to undesired electrostatic fields or discharges. Likewise, in some cases, accumulated electrostatic charge may adversely contribute to accumulation of dust on surfaces and, in turn, increase susceptibility of exposed conductors to undesired discharge events. In the configuration illustrated in FIG. 2A, a boundary wall 226 substantially isolates electronic components within the internal plenum 212 from EHD air mover 220. However, a secondary vent 230 is provided in boundary wall 226 and allows at least some air flow to be drawn through the internal plenum 212 into the EHD motivated flow path 218. An ion barrier 228 positioned across, within or proximate to secondary vent 230 substantially impedes migration of ions generated by EHD device 220 through secondary vent 230 and into internal plenum 212.

In the illustrated configuration, inlet ventilation boundary 222A allows air flow to be drawn across (or past heat transfer surfaces of) one or more of the electronic components within internal plenum 212. Note that the illustrated positioning of inlet ventilation boundary 222A (and indeed, positioning of the electronic components within internal plenum 212) has been selected primarily to simplify depiction. Based on the description herein, persons of ordinary skill in the art will appreciate a wide variety of variations on ventilation boundary and component placements suitable for specific systems and specific design requirements.

In general, ion barrier 228 impedes transit of ions and/or charged particulate from the EHD air mover 220 side of boundary wall 226 into internal plenum 212. Typically, ion barrier 228 operates by electrostatic repulsion. For example, in some implementations, dielectric material provides a surface (whether planar, conformal or configured as a fluid permeable grille, mesh, grid, or filter) on which charge accumulates and thereafter repels ions and particulate of like charge. In some embodiments, one or more dielectric surfaces are formed of polyimide material (or provided as a polyimide film or tape affixed over underlying surfaces or structure) such as marketed by E. I. du Pont de Nemours and Company under the KAPTON trademark. In some embodiments, conductive material electrically isolated from ground may similarly accumulate charge and may be employed to electrostatically repel ions and particulate of like charge.

Relative to the configuration of FIG. 2A, the illustrated ion barrier may be positioned outside or inside internal plenum 212, across the path of air flow drawn through internal plenum 212, on a plenum or enclosure surface, or at any other location suitable to electrostatically impede migration or infiltration of ions through secondary vent 230 into internal plenum 212. In some implementations, the ion barrier can include a charged wire, rod, grid, screen or mesh positioned in or adjacent the path of air flow drawn from internal plenum 212 to provide repulsive electrostatic force. In some implementations, anion barrier may include further surfaces coupled to ground so as to collect ions that elude a primary electrostatically repulsive ion barrier adjacent thereto or provided elsewhere in the system. Thus, ion migration of ions and/or charged particulates may be impeded (at a particular ion barrier) by attraction or repulsion, or both.

In some implementations, an ion barrier surface (e.g., planar, conformal or configured as a fluid permeable grille, mesh, grid, or filter) may be coupled to a desired potential (e.g., a power supply voltage) to provide the desired electrostatic repulsion. In some cases, ion migration barrier 228 may be co-located, or integral with, mechanical filtration. For example, in some implementations, a replaceable or cleanable foam, fabric or other suitable material may be positioned as a particulate barrier adjacent the ion barrier.

Fluid permeable grille, mesh, grid, or filter configurations of ion barrier 228 can span (or at least substantially span) a cross-section of secondary vent 230. In some embodiments, however, ion migration barrier 228 may take the form of surface(s) proximate secondary vent 230 that, whether by charge accumulated thereon or by active charging to a desired potential, nonetheless repel ions and particulate of like charge that would otherwise migrate through secondary vent 230 into internal plenum 212.

In some implementations, the secondary vent 230 and ion barrier 228 are positioned upstream of EHD air mover 220 and the downstream portion of the flow path or air flow 218 is substantially sealed from the internal air plenum 212. In some implementations, positioning of the secondary vent 230 primarily upstream of the EHD air mover 220 can mitigate ingress of ozone into the internal plenum 212. In some implementations, positive pressure within the internal plenum (e.g., as provided by a small mechanical fan not specifically shown) may serve to further mitigate intrusion of ions and/or ozone into the internal plenum 212.

Ozone reducing material may be provided downstream of EHD air mover 220. EMI shielding may also be provided between the EHD air mover 220 and the internal plenum 212, for example, as a grounded conductive surface grille, mesh, or grid (either separate or integral with ion barrier 228) proximate to or substantially spanning secondary vent 230. Some examples of suitable EMI shielding include copper tape, aluminum or other metal foil (e.g., 50-100 microns), or conductive-coated plastic.

Any of a variety of air flow configurations may be provided. For example, and with reference to FIG. 2A, air flow 218 may run substantially parallel to an edge portion of internal plenum 212. Plural EHD air movers 220 may be provided, e.g., as illustrated with reference to FIG. 2B, to both push and pull airflow 218 between inlet and outlet boundaries 222 and 224. In some embodiments, at least a portion of air flow(s) 218 may travel a short path through enclosure 202, for example, as illustrated in FIG. 2C, entering through one or more inlet ventilation boundaries 222 on a major surface of enclosure 202 and exiting one or more outlet ventilation boundaries 224 on an adjacent edge or vice versa. With continued reference to FIG. 2C, EHD's 220 of different sizes or configurations may be arranged to motivate air along respective air paths, including through plenum 212. Any number or combination of inlet and outlet configurations may be used in various device configurations.

In some variations such as illustrated in FIGS. 2A, 2B and 2C, air flow 218 (or a portion thereof) may be drawn through or over a broad surface of internal plenum 212 or through a central chamber or corridor extending through the internal plenum, e.g., over heat generating components within plenum 212. In such configurations, instances of secondary vent 230 and ion barrier 228 are positioned upstream of respective EHD air mover(s) 220. Design and operation of secondary vent 230 and ion barrier 228 will be understood, in each case, based on the foregoing description with respect to FIG. 2A.

Finally, with reference to FIG. 2D, a variation on the design of FIG. 2A illustrates positioning of secondary vent 230 and ion barrier 228 downstream of EHD air mover 220. In the illustrated configuration, a portion of the air flow motivated by EHD air mover 220 flows through internal plenum 212 and out through outlet ventilation boundary 224A. For example, in some embodiments, such flow across (or past heat transfer surfaces of) one or more of the electronic components may contribute to ventilation of the internal plenum, while another portion of the EHD motivated air flow flows over primary heat transfer surfaces 216 and out through outlet ventilation boundary 224.

In the configuration illustrated in FIG. 2D, populations of free ions are typically quite low downstream of collector electrode surfaces of EHD air mover 220. Nonetheless, ion barrier 228 acts to impede transit through secondary vent 230 of charged particulate that may be entrained in the motivated airflow. Preferably, for heat transfer efficiency, secondary vent 230 and ion barrier 228 are upstream of heat transfer surface(s) 216. As before, any of a variety of air flow configurations may be provided and persons of ordinary skill in the art will appreciate suitable variations (including variations akin to those illustrated in FIGS. 2B and 2C) in which secondary vent 230 creates a branch in air flow 218 downstream of EHD air mover 220, through internal plenum 212 and out via an outlet ventilation boundary 224A analogous to that illustrated in FIG. 2D.

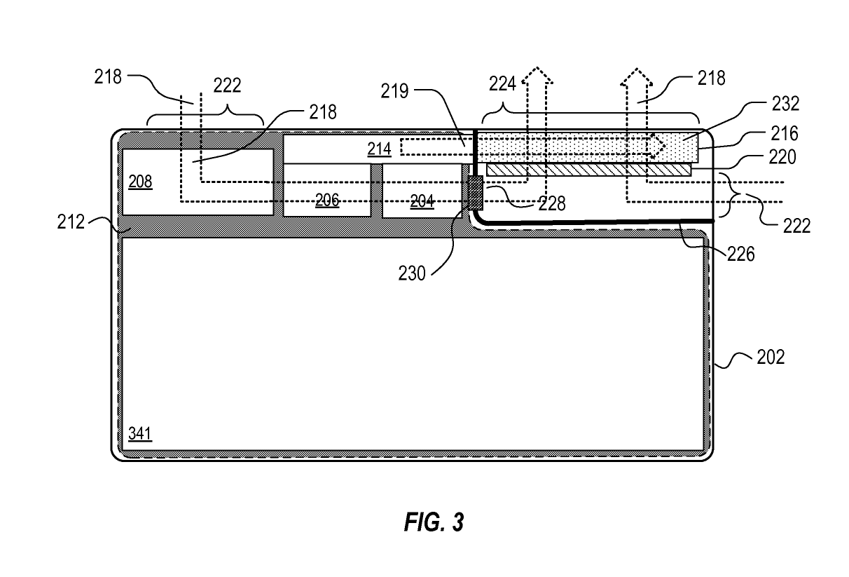

With reference to FIG. 3, an illustrated laptop enclosure 202 is shown in which similar techniques may be employed. In particular, enclosure 202 includes an internal air plenum 212 housing various electronic components 204-208. In the illustration of FIG. 3, a battery 341 occupies a substantial portion of the volume within enclosure 202. As before, an EHD air mover 220 motivates air flow 218 over heat transfer surfaces 216 to expel heat generated by components 204 or 206 and transferred (219) via heat pipe 214. An ion barrier 228 impedes migration of ions from EHD device 220 into an internal air plenum 212, e.g., through secondary vent 230 in a boundary wall 226. In some implementations, ion barrier 228 spans at least a portion of secondary vent 230 and the air flow path from internal plenum 212, e.g., in the form of a charged or chargeable mesh, screen, wire, rod or grid. In some implementations, ion barrier 228 (or multiple ion barrier features) may be placed strategically along a portion of the flow path, e.g., in the form of a charged or chargeable surface interposed along a possible ion migration path toward the internal plenum 212. In some cases, ion barrier 228 (or one of multiple ion barrier features provided) may be positioned just inside internal plenum 212. In some cases, charged or chargeable surfaces may be positioned or formed on and interior surface of enclosure 202 or ducting therein.

As before, any of a variety of charge collection surfaces may be employed to provide electrostatic repulsion. Also as before, dielectric materials, floating conductors and even actively charged surfaces may be employed. In some cases, ion sinks may be provided to capture ions that nonetheless elude a repulsive ion barrier.

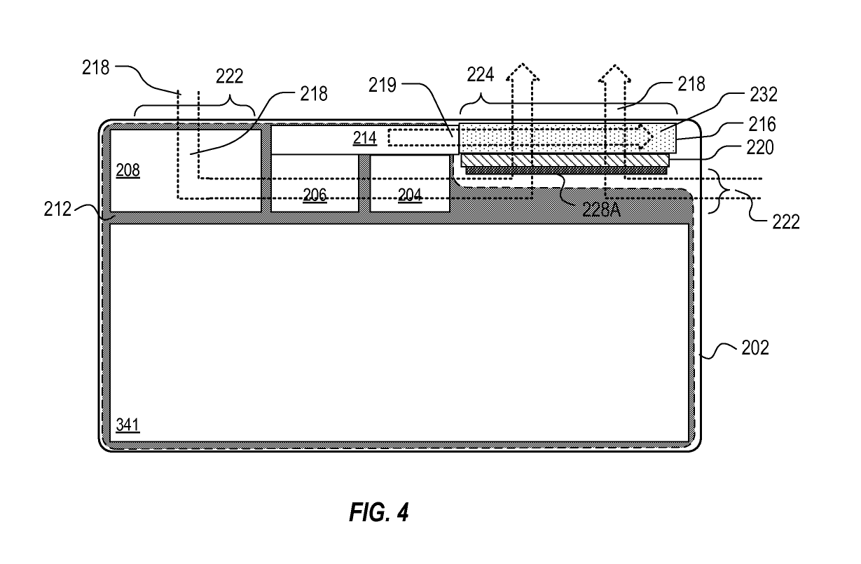

Although internal air plenums may be defined (at least in part) by a boundary wall, and ion migration into the internal plenum may be managed using an ion barrier suitably positioned within or adjacent to a secondary vent in such a boundary wall to impede ion infiltration or migration, some embodiments may (alternatively or additionally) seek to impede upstream ion migration at the intake of an EHD air mover itself. For example, FIG. 4 depicts another embodiment, similar to that depicted in FIG. 3 in which the ion barrier (here, ion barrier 228A) is substantially coextensive with an inlet of EHD air mover 220 to prevent upstream migration of ions from EHD air mover 220. As before, ion barrier 228A can be a charged or floating potential mesh, screen, electrode, or other surface along the air flow to mitigate ion migration upstream within the air flow(s).

In some implementations, an ion barrier is positioned proximate EHD air mover 220, e.g., immediately upstream relative to the motivated air flow. In some implementations, more than one ion barrier 228, 228A or multiple types or instances of ion barrier 228, 228A can be used to impede ion migration into internal plenum 212. For example, some embodiments may combine features of FIGS. 3 and 4 to provide both an EHD inlet positioned ion barrier 228A and an ion barrier 228 in or adjacent to a secondary vent in a boundary wall. Furthermore, in some embodiments, both ion repelling and ion attracting surfaces may be employed to more effectively exclude ions from internal plenum 212.

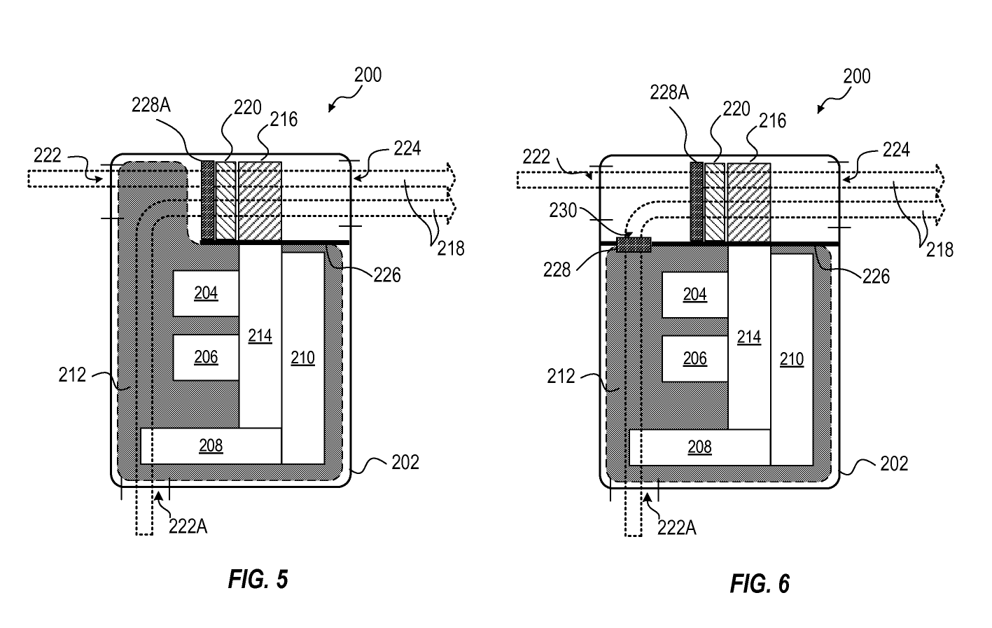

FIGS. 5 and 6 depict analogous configurations relative to pad- or smartphone-type scales and form factors previously described. In particular, FIG. 5 depicts a plan view of an illustrative device configuration (including an EHD air mover 220 and components within an internal plenum 212) in which an ion barrier 228 is positioned at, adjacent to, or is integral with an intake portion of the EHD air mover 220 and impedes ion and/or charged particulate migration back into the internal air plenum 212. FIG. 6 depicts (in plan view) a variation in which, in addition to the intake-positioned ion barrier (here ion barrier 228A), a further ion barrier 228 is positioned at, or adjacent to, a secondary vent 230 that allows air flow to be drawn from the internal air plenum 212 and into the EHD motivated flow path 218, but further impedes ion and/or charged particulate infiltration upstream into internal air plenum 212. Embodiments in accord with FIGS. 5 and 6, and suitable variations thereon, will be understood with reference to variations described in greater detail relative to FIGS. 2A, 2B, 2C, 2D, 3 and/or 4.

FIGS. 7, 8, 9A, 10 and 11 depict side cross-sectional views of illustrative EHD air mover designs suitable for use in various of the device configurations illustrated herein. For example, instances of EHD air mover 220 illustrated and described with respect to FIGS. 2A, 2B, 2C, 2D, 3, 4, 5 and/or 6, may be provided in accord with one or more of the EHD air mover designs illustrated.

In each case, sidewall surfaces 493 extending toward an intake portion of the illustrated variant of EHD air mover 220 may be formed of dielectric material. As before, dielectric surfaces may (in some embodiments) be formed of polyimide material (or provided as a polyimide film or tape affixed over underlying surfaces or structure) such as marketed by E. I. du Pont de Nemours and Company under the KAPTON trademark. During operation of the EHD air movers, supply 490 establishes high voltage (typically multiple KV voltages) between an emitter electrode 491 and collector electrodes 492 which, in turn, generates ions and accelerates the generated ions (together with convoyed fluid) in a net downstream direction 499. In the illustrations, emitter electrodes 491 are coupled to a positive high voltage terminal of power supply 490 (illustratively +3.5 KV, although specific voltages and, indeed, any supply voltage waveforms may be matters of design choice) and collector electrodes 492 are coupled to a local ground. See U.S. Pat. No. 6,508,308, which is incorporated herein by reference in its entirety, for a description of suitable designs for power supply 490. Given the substantial voltage and short distances involved (perhaps 1 mm or less) between emitter electrode 491 and leading surfaces of collector electrodes 492, strong electrical fields are developed which impose a net downstream motive force on positively charged ions (or particles) in the fluid. Field lines illustrate (generally) spatial aspects of the resulting electric field and spacing of the illustrated field lines is indicative of intensity.

Notwithstanding the dominant downstream flow, some charge generated at emitter electrode 491 migrates to the dielectric surfaces 493 where it is retained and thereafter imposes a repulsive electrostatic force on additional ions and charged particulate. In this way, charged dielectric sidewall surfaces 493 shape fields in the EHD channel and provide a barrier to upstream ion migration. The resulting ion barrier extends upstream of emitter electrode 491 to provide an intake-positioned ion barrier (e.g., ion barrier 228A, see FIGS. 4, 5 and 6). Thus, in some embodiments, an EDD intake positioned ion barrier may be integrally formed with EHD air mover 220 or a subassembly that, for a given design or in a particular supply chain, constitutes EHD air mover 220. In some embodiments, an EHD air mover 220 may be augmented (at some stage of assembly) with a separate intake positioned ion barrier.

FIG. 7 depicts an EHD air mover design in which dielectric suitable to capture and retain charge along sidewalls upstream of emitter electrode 491 provides a barrier to upstream migration of ions. These surfaces, which are provided upstream of emitter electrode 491, shape the previously described electric field and, in some cases, provide a suitable and sufficient barrier to upstream migration of ions. For example, relative to the illustration of FIG. 7, dielectric surfaces 493 are provided on which positive charge (such as from ions generated at a corona discharge type instance of emitter electrode 491 or elsewhere) tends to accumulate. Because dielectric surfaces 493 do not provide an attractive path to ground, a net positive charge tends to accumulate and thereafter operate to electrostatically repel like charges. As a result, dielectric surfaces 493 are electrostatically operative as a barrier to upstream ion migration. Upstream dielectric surfaces 493 also tend to electrostatically mask any otherwise attractive paths to ground, thereby shaping the previously described electric field in the primarily downstream direction toward collector electrodes 492.

To improve performance, an air gap may be provided between leading edges of collector electrodes 492 and adjacent portions of dielectric surfaces 493. For example, in some embodiments, an air gap may be provided in the form of a shallow trench formed in dielectric surfaces 493.

Optionally, in some embodiments, one or more conductive paths to ground may be provided further upstream of dielectric surfaces 493 to capture ions that may nonetheless migrate upstream. FIG. 8 adds optional ion sinks 428 to enhance performance of an EHD intake positioned ion barrier provided by dielectric sidewalls 493. In some ventilated device embodiments, such a conductive path to ground may be provided proximate an inlet ventilation boundary.

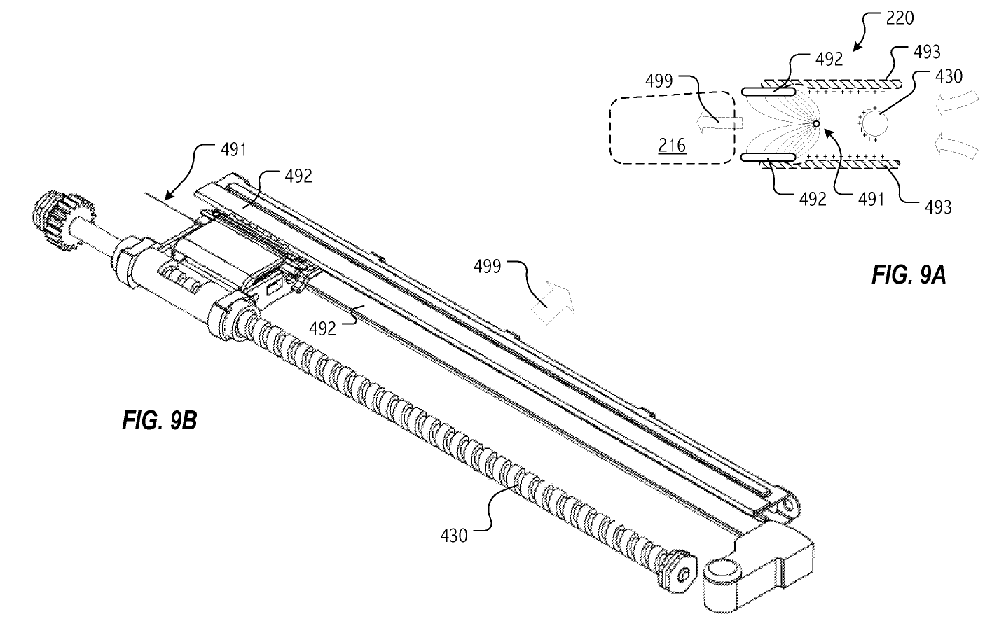

FIGS. 9A and 9B illustrate an EHD air mover design in which a carriage is provided to transit electrode conditioning and/or cleaning surfaces over at least a portion of emitter and collector electrode surfaces (491, 492). In some designs, an upstream lead screw or worm gear 430 that is used to motivate and guide the carriage provides additional upstream charge collection surfaces as part of an EHD intake positioned ion barrier. In some embodiments, as an alternative to (or in addition to) the illustrated screw or gear, a shaft, rod or other upstream surface may act as a guide for electrode conditioning and/or cleaning surfaces. Charged or chargeable surfaces of such a guide may likewise provide a repulsive ion barrier. Specifically, the dielectric or electrically isolated conductive surfaces of such a lead screw, worm gear, shaft, rod or guide may capture and retain charge from ions generated at emitter electrode 491 and, like other ion barriers described herein, thereafter provide a repulsive electrostatic force. As before, the charged or chargeable surface (here lead screw or worm gear 430) can be set at a voltage or allowed to float.

Although not specifically illustrated, additional ion barrier surfaces may be provided to further impede ion migration upstream. For example, and as before, a dielectric or electrically isolated conductive mesh, grille, grate or other fluid permeable structure charged to attract or repel ions may be provided across or adjacent an inlet of an EHD module to further impede upstream ion migration.

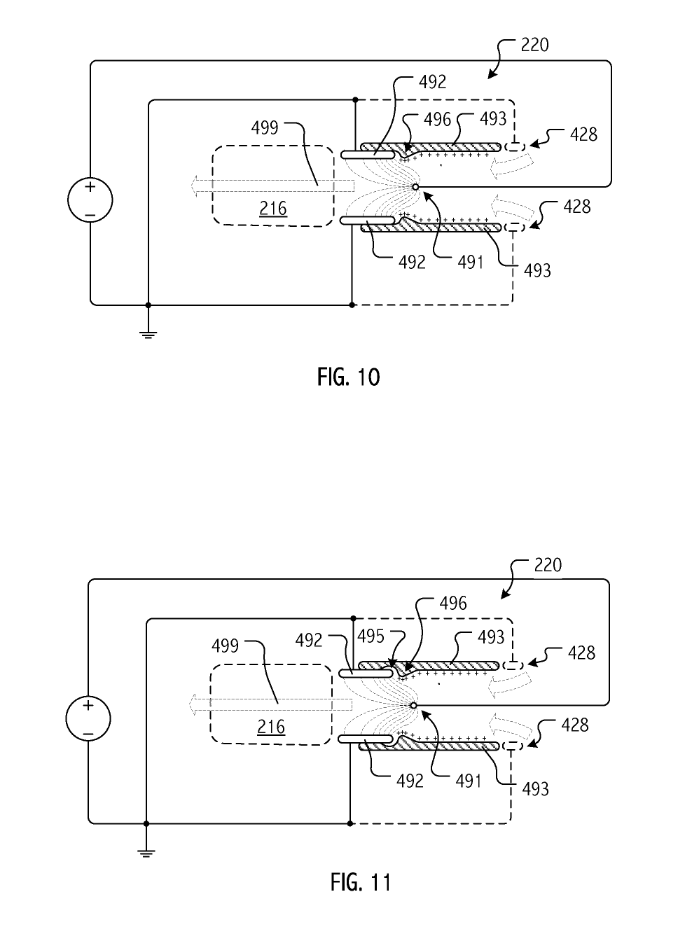

FIGS. 10 and 11 depict additional sidewall features that contribute to field shaping in some EHD air mover 220 implementations. For example, in some embodiments (and as illustrated in FIG. 10), a berm 496 formed in dielectric surfaces 493 just upstream of leading edges of collector electrodes 492 may create (during EHD operation) a narrow region of accumulated charge concentration and thereby shape the electric field in such a way that ion flow is diverted around the portion of dielectric surfaces 493 immediately adjacent to the leading edge of respective collector electrodes 492. The localized charge concentration illustrated at the convex surface contour of berm 496 tends to shadow those portions of dielectric surfaces 493 most closely proximate to leading edges of collector electrodes 492 from charge accumulation. As a result, likelihood of arcing electrostatic discharge from these most closely proximate portions is reduced.

In some embodiments such as illustrated in FIG. 11, both a berm 496 and a shallow trench 495 are formed in dielectric surfaces 493 just upstream of leading edges of collector electrodes 492. As before, the structure creates a narrow region of accumulated charge concentration and thereby shape the electric field in such a way that ion flow is diverted around the portion of dielectric surfaces 493 immediately adjacent to the leading edge of respective collector electrodes 492. Shallow trench 495 provides a further air gap to limit arcing electrostatic discharge.

### Additional Embodiments

Some implementations of thermal management systems described herein employ EFA or EHD devices to motivate flow of a fluid, typically air, based on acceleration of ions generated as a result of corona discharge. Other implementations may employ other ion generation techniques and will nonetheless be understood in the descriptive context provided herein. Using heat transfer surfaces, heat dissipated by electronics (e.g., microprocessors, graphics units, etc.) and/or other electronic system components can be transferred to the fluid flow and exhausted. Heat transfer paths, e.g., heat pipes, are provided to transfer heat from a heat source within the internal plenum to a location(s) within the enclosure where air flow motivated by an EHD device(s) flows over heat transfer surfaces to dissipate the heat.

In some implementations, enclosure and/or duct surfaces along the flow path can be provided with an ozone reducing material. In some applications, an ozone catalytic or reactive material can be provided on surfaces exposed to the internal air plenum. Similarly, ozone resistive or tolerant coatings can be provided on surfaces exposed to the internal air plenum. Ozone reducing materials can include ozone catalysts, ozone binders, ozone reactants or other materials suitable to react with, bind to, or otherwise reduce or sequester ozone. In some implementations, the ozone reducing material is a catalyst selected from a group that includes: manganese (Mn); manganese dioxide (MnO₂); gold (Au); silver (Ag); silver oxide (Ag₂O); and an oxide of nickel (Ni); and an oxide of manganese preparation. Ozone reducing material can be applied to internal enclosure surfaces and/or to the surface of electronic components within enclosure 202. Ozone reducing material can additionally be applied to electronic system components, e.g., components 202-210. Similarly, surfaces of any number of the electronic components within enclosure 202, and even internal enclosure surfaces can be provided with ozone tolerant, or ozone resistant coating to mitigate the effects of ozone.

In some implementations, an EFA or EHD air cooling system or other similar ion action device may be integrated into an operational system such as a laptop, tablet or desktop computer, a projector or video display device, etc., while other implementations may take the form of subassemblies. Various features may be used with different devices including EFA or EHD devices such as air movers, film separators, film treatment devices, air particulate cleaners, photocopy machines and cooling systems for electronic devices such as computers, laptops and handheld devices. One or more EHD cooled devices can include one of a computing device, projector, copy machine, fax machine, printer, radio, audio or video recording device, audio or video playback device, communications device, charging device, power inverter, light source, medical device, home appliance, power tool, toy, game console, set-top console, television, and video display device.

While the foregoing represents a description of various implementations of the invention, it is to be understood that the claims below recite the features of the present invention, and that other implementations, not specifically described hereinabove, fall within the scope of the present invention.

What is claimed is:

1. An electronic system comprising:
an enclosure; and
a plurality of electronic components within the enclosure having respective surfaces exposed to an internal air plenum,
the enclosure having inlet and outlet ventilation boundaries together with an EHD air mover disposed therein to internal air plenum along a flow path between the inlet and outlet ventilation boundaries, wherein at least a portion of the flow path transits the internal air plenum; and
an ion barrier positioned to impede ion migration from the EHD air mover into the internal air plenum.

2. The electronic system of claim 1, further comprising:
a boundary wall at least partially defining the internal air plenum; and
a secondary vent positioned to allow at least a portion of the motivated air flow to transit the internal air plenum.

3. The electronic system of claim 2,
wherein the secondary vent includes an opening through the boundary wall.

4. The electronic system of claim 2,
wherein the ion barrier is positioned proximate to the secondary vent to impede ion migration therethrough.

5. The electronic system of claim 2,
wherein the ion barrier is positioned in, or proximate to, an inlet portion of the EHD air mover to impede ion migration toward the secondary vent.

6. The electronic system of claim 5, further comprising:
an additional ion barrier positioned proximate to the secondary vent to further impede ion migration from the EHD air mover into the internal air plenum.

7. The electronic system of claim 1,
wherein the ion barrier is positioned in, or proximate to, an inlet portion of the EHD air mover to impede ion migration toward the internal air plenum.

8. The electronic system of claim 1,
wherein the ion barrier includes one or more surfaces interposed upstream of an emitter electrode of the EHD air mover in a portion of the flow path between the internal air plenum and the emitter electrode.

9. The electronic system of claim 8,
wherein the one or more surfaces of the interposed ion barrier are configured to collect and retain charge that migrates from the emitter electrode during operation of the EHD air mover such that migration or flow of further ions or charged particulate is impeded by repulsive electrostatic force.

10. The electronic system of claim 8,
wherein the one or more surfaces of the interposed ion barrier are coupled to a repelling electrical potential such that migration or flow of ions or charged particulate is impeded by repulsive electrostatic force.

11. The electronic system of claim 1,
wherein the ion barrier includes at least one of an electrostatically chargeable wire, rod, strip, grill, mesh and screen.

12. The electronic system of claim 1,
wherein the ion barrier includes one or more electrostatically chargeable side walls along the flow path.

13. The electronic system of claim 1,
wherein the ion barrier includes an electrostatically chargeable surface of an electrode conditioning mechanism.

14. The electronic system of claim 13,
wherein the electrostatically chargeable surface of the electrode conditioning mechanism includes an elongate guide shaft, drive screw or worm gear interposed in the flow path.

15. The electronic system of claim 1,
wherein the ion barrier is formed, at least in part, of dielectric or electrically isolated conductive material that accumulates static charge during operation of the EHD air mover.

16. The electronic system of claim 1,
wherein the ion barrier is formed, at least in part, of conductive material coupled to an ion repelling potential.

17. The electronic system of claim 1,
wherein the ion barrier is formed as or of a fluid permeable material.

18. The electronic system of claim 1,
wherein the ion barrier includes one or more surfaces interposed downstream of a collector electrode of the EHD air mover in a portion of the flow path between the collector electrode and the internal air plenum.

19. The electronic system of claim 18,
wherein the one or more surfaces of the interposed ion barrier are coupled to a repelling electrical potential such that migration or flow of ions or charged particulate is impeded by repulsive electrostatic force.

20. The electronic system of claim 18,
wherein the one or more surfaces of the interposed ion barrier are configured to collect and retain charge that migrates or flows from an emitter electrode past the collector electrode during operation of the EHD air mover such that migration or flow of ions or charged particulate is impeded by repulsive electrostatic force.

21. The electronic system of claim 1,
wherein the ion barrier includes an ion repelling portion and an adjacent ion attracting portion, the ion repelling and attracting portions closely proximate but oriented such that the ion repelling portion is interposed in or along the flow between an emitter electrode and the internal air plenum.

22. The electronic system of claim 1, further comprising:
ozone catalytic or reactive material disposed on surfaces exposed to the internal air plenum.

23. The electronic system of claim 1, further comprising:
ozone resistant or tolerant coatings on surfaces exposed to the internal air plenum.

24. The electronic system of claim 1,
wherein a substantial portion of the air flow motivated by the EHD air mover is drawn through the internal air plenum.

25. A method of ventilating an electronic system, the method comprising:
with an EHD air mover, generating ions and accelerating the generated ions in the presence of an electrical field to thereby motivate air flow over heat transfer surfaces and along a flow path between inlet and outlet ventilation boundaries of an enclosure, wherein at least a portion of the air flow transits an internal air plenum housing a plurality of electronic components; and
electrostatically impeding ion migration from the EHD air mover into the internal air plenum.

26. The method of claim 25, further comprising:
on a surface interposed in or along the flow path, collecting and retaining charge that migrates from an emitter electrode during operation of the EHD air mover such that migration or flow of further ions or charged particulate is impeded by repulsive electrostatic force.

27. The method of claim 25, further comprising:
charging a surface interposed in or along the flow path to a repelling electrical potential such that migration or flow of ions or charged particulate is impeded by repulsive electrostatic force.

28. The method of claim 25,
wherein the internal air plenum is upstream of the EHD air mover relative to the motivated air flow.

29. The method of claim 25,
wherein the internal air plenum is downstream of the EHD air mover relative to the motivated air flow.

30. The method of claim 25, further comprising:
drawing air from the internal air plenum into the motivated air flow, wherein the electrostatically impeded ion migration includes upstream migration into the internal air plenum of ions generated at an emitter electrode of the EHD air mover.

31. The method of claim 25, further comprising:
exhausting a portion of the motivated air flow through the internal air plenum, wherein the electrostatically impeding includes diverting away from the internal air plenum ions or charged particulate entrained in the motivated air flow downstream of a collector electrode of the EHD air mover.

32. The method of claim 25, further comprising:
transiting at least a portion of the air flow through the internal air plenum and over ozone catalytic or reactive material on exposed surfaces within the internal air plenum.

33. The method of claim 25, further comprising:
transiting at least a portion of the air flow through the internal air plenum and past ozone resistive or tolerant coatings on exposed surfaces within the internal air plenum.

34. A method of making a product, the method comprising:
positioning an EHD air mover within an electronic device enclosure to motivate air flow along a flow path between the inlet and outlet ventilation boundaries of the electronic device enclosure; and
providing within the electronic device enclosure an ion barrier positioned therewithin to substantially impede migration of ions generated at an emitter electrode of the EHD air mover into an internal air plenum.

35. The method of claim 34, further comprising:
providing a secondary vent in a boundary wall positioned to at least partially define the internal air plenum.

36. The method of claim 35, further comprising:
providing an electrostatically chargeable wire, rod, strip, grill, mesh or screen across or proximate to the secondary vent to at least partially define the ion barrier.

37. The method of claim 34, further comprising:
providing an electrostatically chargeable surface in, or proximate to, an inlet portion of the EHD air mover to collect impede upstream ion migration toward the internal air plenum.

38. The method of claim 37, wherein the provided electrostatically chargeable surface includes at least one of:
a wire, rod, strip, grill, mesh and screen; and
side walls along the flow path formed of dielectric material.

39. The method of claim 37, further comprising:
providing an electrode conditioning mechanism operable at successive times throughout the operating life of the EHD air mover,
wherein the electrostatically chargeable surface includes an elongate guide shaft, drive screw or worm gear of the electrode conditioning mechanism interposed in the flow path.
